(19) United States
(12) Patent Application Publication
(10) Pub. No.: US 2002/0131293 A1
(43) Pub. Date: Sep. 19, 2002

(54) BIT line sense amplifier suppressing a pull-up voltage of a BIT signal and semiconductor memory device having the same

(76) Inventors: Soon Won Hong, Seoul (KR); Jae Hyung Kim, Sungnam-shi (KR)

Correspondence Address: CANTOR COLBURN, LLP, 55 GRIFFIN ROAD SOUTH, BLOOMFIELD, CT, 06002

(21) Appl. No.: 10/060,477

(22) Filed: Jan. 30, 2002

(30) Foreign Application Priority Data
Mar. 13, 2001 (KR) 2001-0012902
Oct. 24, 2001 (KR) 2001-0065573
Oct. 24, 2001 (KR) 2001-0065574

(51) Int. Cl. G11C 11/24

(52) U.S. Cl. 365/149

(57) ABSTRACT

A bit line sense amplifier suppressing a pull-up voltage of a bit signal and a semiconductor memory device having the same. The bit line sense amplifier includes an amplifying portion, a pull-up portion and a pull-down portion. The amplifying portion is disposed between a pull-up node and a pull-down node, and amplifies a bit signal and a complementary bit signal. The amplifying portion has two inverters cross-coupled as a latch. The pull-up portion is disposed between a power supply node and the pull-up node, and pulls up a voltage level of the pull-up node in response to a pull-up control signal. The pull-down portion is disposed between a ground voltage and the pull-down node and is controlled by a pull-down control signal. The pull-down portion pulls down a voltage level of the pull-down node. The pull-up portion includes a first transistor and a second transistor. The first transistor drops a voltage level of the power supply node by a predetermined voltage level. The second transistor provides a voltage of the power supply node dropped by the first transistor to the pull-up node. In the NMOS pull-up type bit line sense amplifier according to the present invention, the pull-up voltage of the pull-up node is limited to (VDD-Vt) and a maximum pull-up voltage of the bit signal is also limited to (VDD-Vt). Therefore, the semiconductor memory device having the bit line sense amplifier in the invention can prevent excessive current consumption and stress.

### BACKGROUND OF THE INVENTION

1. Field of the Invention

The invention relates to a semiconductor device, and more particularly, to a bit line sense amplifier, and a semiconductor memory device having the bit line sense amplifier.

2. Description of the Related Art

Generally, a semiconductor memory device has a memory cell storing data and a bit line sense amplifier amplifying the data. FIG. 1 is a circuit diagram illustrating a conventional bit line sense amplifier. The conventional bit line sense amplifier 100 includes an amplifying portion 101, a pull-up transistor 103 and a pull-down transistor 105. The amplifying portion 101 includes two inverters cross-coupled as a latch, senses a bit signal BIT and a complementary bit signal/BIT, and then amplifies the bit signal BIT and the complementary bit signal/BIT. During a sensing operation, the pull-up transistor 103 drives a pull-up node N102 to the level of a power voltage VDD in response to a pull-up control signal SPC1. The pull-down transistor 105 drives a pull-down node N104 to the level of a ground voltage VSS in response to a pull-down control signal SNC1.

Recently, in order to increase the density of the semiconductor memory device, a technology of the use of an NMOS transistor for a store capacitor of the memory cell has been developed. A maximum voltage level capable of being stored in the store capacitor is (VDD-Vt). The VDD is an external power voltage and the Vt is a threshold voltage of the NMOS transistor. That is to say, even though a voltage level of the bit signal BIT rises considerably, the maximum voltage level capable of being stored in the store capacitor is limited to (VDD-Vt).

According to the conventional bit line sense amplifier shown in FIG. 1, the voltage level of the bit signal BIT goes up to that of the external power voltage VDD. That is, in the conventional bit line sense amplifier, current consumption and a stress, etc. are excessively increased as the voltage level of the bit signal BIT rises.

### SUMMARY OF THE INVENTION

To solve the above problems, it is an object of the invention to provide a bit line sense amplifier suppressing a pull-up voltage of a bit signal, and a semiconductor memory device having the same.

In one aspect, a semiconductor memory device includes a bit line sense amplifier for sensing a bit signal and a complementary bit signal, and amplifying the bit signal and the complementary bit signal; and a memory cell storing the bit signal. The memory cell has an NMOS transfer transistor, which is controlled by a word signal, for transferring the bit signal; and a capacitor for storing the bit signal transferred by the NMOS transfer transistor. The bit line sense amplifier has an amplifying portion disposed between a pull-up node and a pull-down node; a pull-up portion disposed between a power supply node and the pull-up node; and a pull-down portion disposed between a ground voltage and the pull-down node. The amplifying portion includes two inverters cross-coupled as a latch, and amplifies the bit signal and the complementary bit signal. The pull-up portion has a first NMOS transistor, which is controlled by a control signal, pulling up a voltage level of the pull-up node. The pull-down portion has a second NMOS transistor, which is controlled by the control signal, pulling down a voltage level of the pull-down node. The word signal and the control signal are activated with a voltage level substantially equal to that of the power supply node.

In another aspect, a semiconductor memory device also includes a bit line sense amplifier for sensing a bit signal and a complementary bit signal, and amplifying the bit signal and the complementary bit signal; and a memory cell for storing the bit signal. The memory cell has an NMOS transfer transistor, which is controlled by a word signal, for transferring the bit signal; and a capacitor for storing the bit signal transferred by the NMOS transfer transistor. The bit line sense amplifier has an amplifying portion disposed between a pull-up node and a pull-down node; a pull-up portion disposed between a power supply node and the pull-up node; and a pull-down portion disposed between a ground voltage and the pull-down node. The amplifying portion includes two inverters cross-coupled as a latch, and amplifies the bit signal and the complementary bit signal. The pull-up portion has a first NMOS transistor, which is controlled by a pull-up control signal, for pulling up a voltage level of the pull-up node. The pull-down portion has a second NMOS transistor, which is controlled by a pull-down control signal, for pulling down a voltage level of the pull-down node. The pull-up control signal is activated before the pull-down control signal, in order that the first NMOS transistor is controlled together with the second NMOS transistor at a predetermined timing.

Preferably, the pull-up control signal, the pull-down control signal and the word signal are activated with a voltage level substantially equal to that of the power supply node.

In still another aspect, a semiconductor memory device also includes a bit line sense amplifier sensing a bit signal and a complementary bit signal, and amplifying the bit signal and the complementary bit signal; and a memory cell storing the bit signal. The memory cell has an NMOS transfer transistor, which is controlled by a word signal, for transferring the bit signal; and a capacitor storing the bit signal transferred by the NMOS transfer transistor. The bit line sense amplifier has an amplifying portion disposed between a pull-up node and a pull-down node; a pull-up portion disposed between a power supply node and the pull-up node; and a pull-down portion disposed between a ground voltage and the pull-down node. The amplifying portion includes two inverters cross-coupled as a latch, and amplifies the bit signal and the complementary bit signal. The pull-up portion is controlled by a control signal and pulls up a voltage level of the pull-up node. The pull-down portion is controlled by the control signal and pulls down a voltage level of the pull-down node. The pull-up portion has a first transistor for dropping a voltage level of the power supply node by a predetermined voltage level; and a second transistor, which is controlled by the control signal, for providing the voltage of the power supply node dropped by the first transistor to the pull-up node.

In still another aspect, there is provided a bit line sense amplifier for a semiconductor memory device. The bit line sense amplifier includes an amplifying portion disposed between a pull-up node and a pull-down node, a pull-up portion disposed between a power supply node and the pull-up node, and a pull-down portion disposed between a ground voltage and the pull-down node. The amplifying portion includes two inverters cross-coupled as a latch, and amplifies a bit signal and a complementary bit signal. The pull-up portion pulls up a voltage level of the pull-up node in response to a pull-up control signal. The pull-down portion is controlled by a pull-down control signal and pulls down a voltage level of the pull-down node. The pull-up portion has a first transistor for dropping a voltage level of the power supply node by a predetermined voltage level; and a second transistor, controlled by the pull-up control signal, for providing the voltage of the power supply node dropped by the first transistor to the pull-up node. Preferably, the first transistor is an NMOS transistor.

### BRIEF DESCRIPTION OF THE DRAWINGS

The foregoing and further features and advantages of the invention will become more apparent from the following description and the accompanying drawings, in which the same reference numerals indicate the same or corresponding parts:

FIG. 1 is a circuit diagram for a conventional bit line sense amplifier;

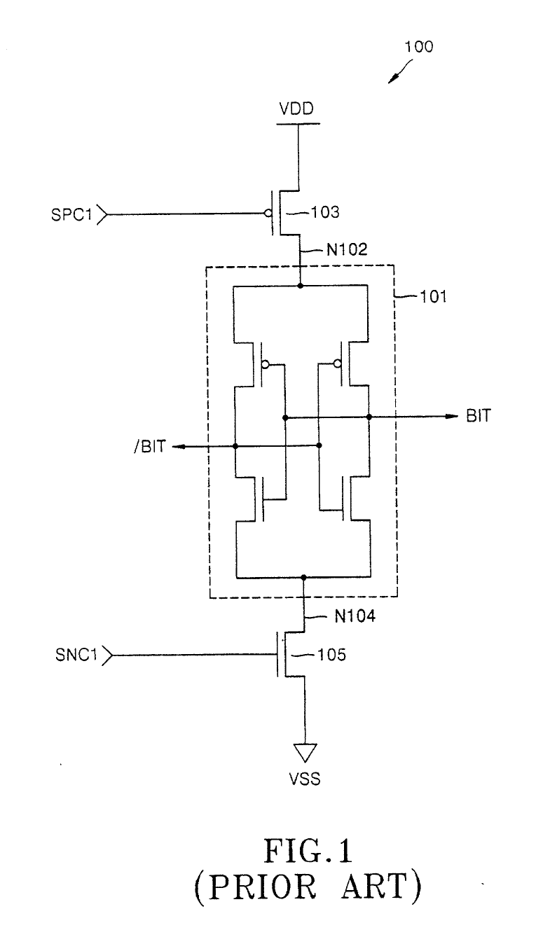

FIG. 2 is a schematic block diagram for explaining a bit line sensing operation in a semiconductor memory device having a bit line sense amplifier according to a first embodiment of the invention;

FIG. 3 is a circuit diagram for a memory cell shown in FIG. 2;

FIG. 4 is a circuit diagram for a bit line sense amplifier shown in FIG. 2;

FIG. 5 is a schematic block diagram for explaining a bit line sensing operation in a semiconductor memory device having a bit line sense amplifier according to a second embodiment of the invention;

FIG. 6 is a circuit diagram for a bit line sense amplifier shown in FIG. 5;

FIG. 7 is a timing diagram of a pull-up control signal SUPC and a pull-down control signal SDNC shown in FIG. 5;

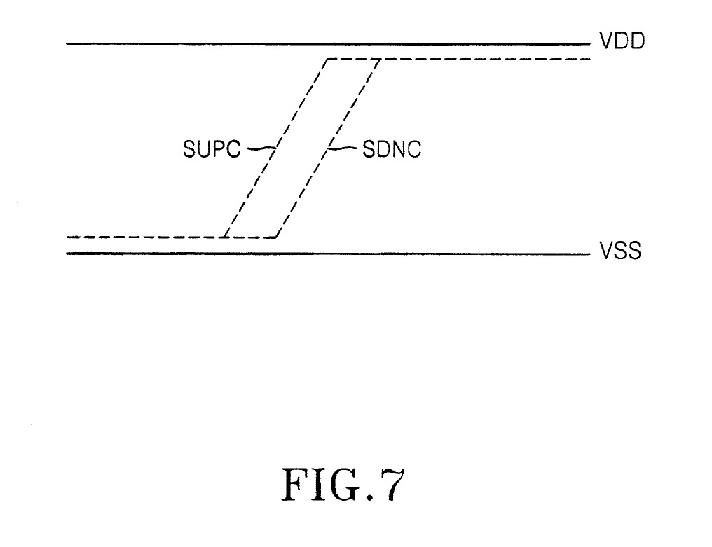

FIG. 8 is a schematic block diagram for explaining a bit line sensing operation in a semiconductor memory device having a bit line sense amplifier according to a third embodiment of the invention;

FIG. 9 is a circuit diagram for a bit line sense amplifier shown in FIG. 8;

FIG. 10 is a timing diagram of a pull-up control signal SPC2 and a pull-down control signal SNC2 shown in FIG. 9; and

FIG. 11 is a drawing for comparing pull-up voltages of bit signals in the conventional art and the embodiments of the present invention.

### DESCRIPTION OF THE PREFERRED EMBODIMENTS

### FIRST EMBODIMENT

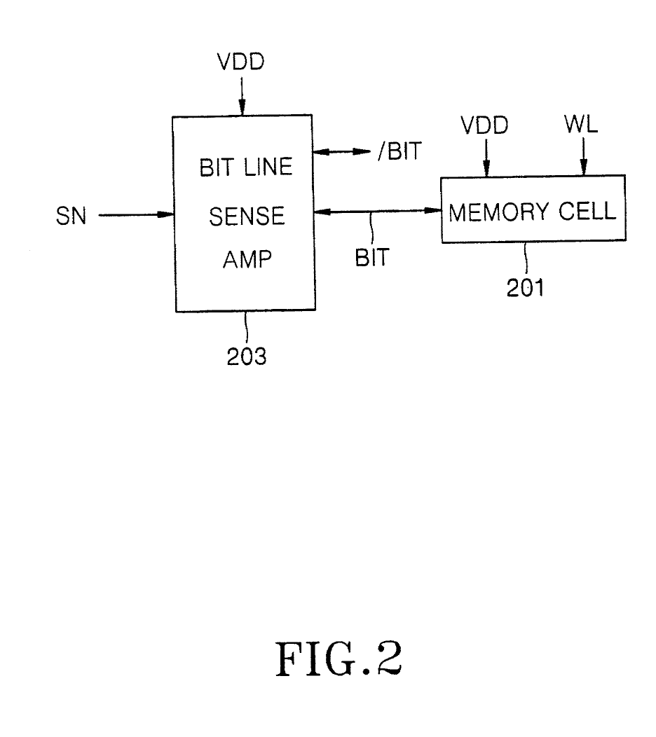

FIG. 2 is a schematic block diagram for explaining a bit line sensing operation in a semiconductor memory device having a bit line sense amplifier according to a first embodiment of the invention. A bit line sense amplifier 203 senses a bit signal BIT and a complementary bit signal/BIT, and amplifies them. The bit line sense amplifier 203 is controlled by a control signal SN. A memory cell 201 provides the bit signal BIT to the bit line sense amplifier 203, and stores the bit signal BIT amplified by the bit line sense amplifier 203.

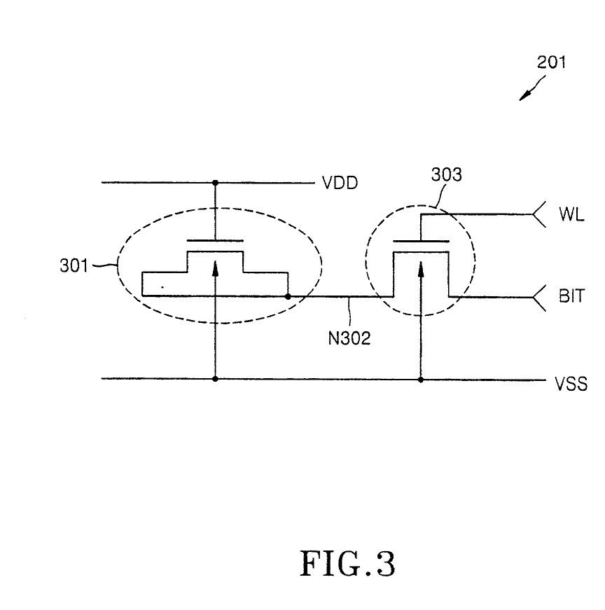

FIG. 3 is a circuit diagram for the memory cell 201 shown in FIG. 2. Referring to FIG. 3, each of a capacitor 301 and a transfer transistor 303 of the memory cell 201 is formed with an NMOS transistor. Therefore, a maximum voltage level capable of being stored in a store node N302 is substantially equal to that of (Vword−Vt). The Vword represents a voltage level of a word signal WL during activation and the Vt represents a threshold voltage of the transfer transistor 303. That is, even though a voltage level of the bit signal BIT rises considerably, the maximum voltage level stored in the store node N302 is lower than Vword by Vt. In a preferred embodiment, the word signal is activated to an external power voltage VDD. Also, the word signal can be activated to a pumping voltage. The level of the pumping voltage is higher than that of the external power voltage VDD.

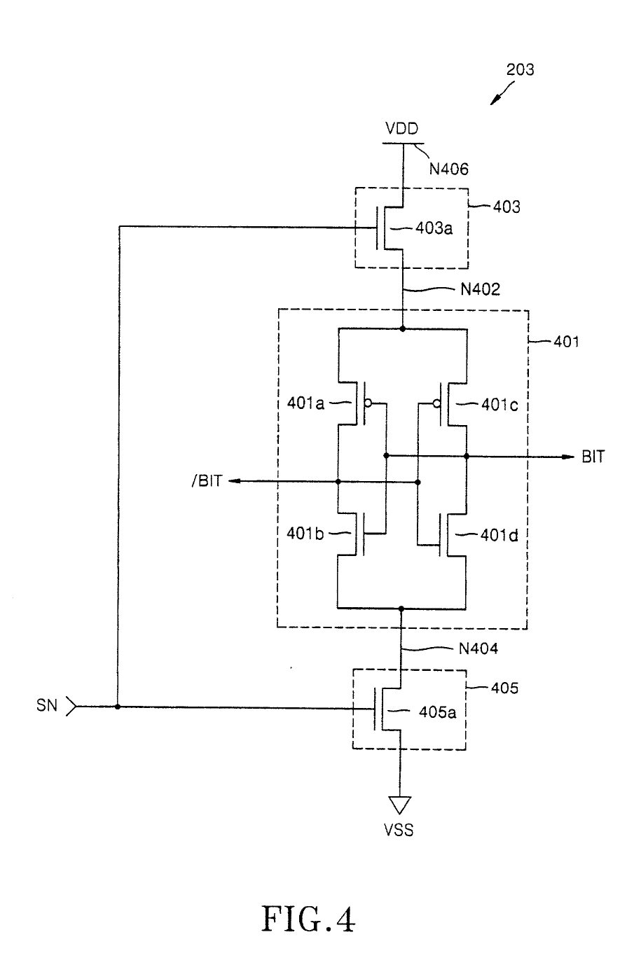

FIG. 4 is a circuit diagram for the bit line sense amplifier 203 shown in FIG. 2. Referring to FIG. 4, the bit line sense amplifier 203 includes an amplifying portion 401, a pull-up portion 403 and a pull-down portion 405. The amplifying portion 401 includes two inverters cross-coupled as a latch. One of the inverters is formed with a PMOS transistor 401a and an NMOS transistor 401b, and the other of the inverters is formed with a PMOS transistor 401c and an NMOS transistor 401d. Outputs of the two inverters are the bit signal BIT and the complementary bit signal/BIT, respectively. Sources of the PMOS transistors 401a and 401c are coupled to a pull-up node N402, and sources of the NMOS transistors 401b and 401d are coupled to a pull-down node N404.

The pull-up portion 403 is formed with an NMOS transistor 403a, of which a source is coupled to the pull-up node N402 and a drain is coupled to a power supply node N406. A voltage level supplied to the power supply node N406 is substantially equal to that of the word signal WL. Preferably, the voltage supplied to the power supply node N406 is the external power voltage VDD. Also, it is preferred that the NMOS transistor 403a has a threshold voltage substantially equal to or less than that of the transfer transistor 303 shown in FIG. 3.

The pull-down portion 405 is formed with an NMOS transistor 405a, of which a source is coupled to a ground voltage VSS and a drain is coupled to the pull-down node N404.

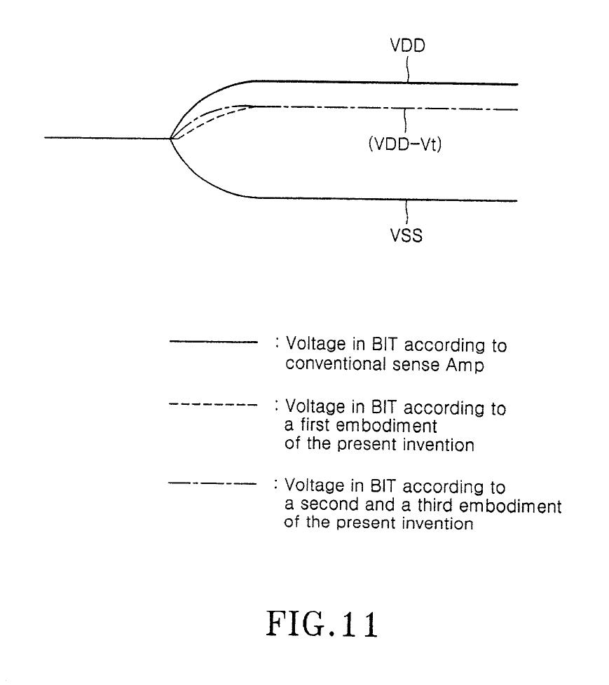

The NMOS transistors 403a and 405a are controlled by the control signal SN. A voltage level of the control signal SN goes up to the level of the external power voltage VDD during a bit line sensing operation. Consequently, the voltage of the bit signal BIT is amplified to (VDD−Vt) by the amplifying portion 401, which is shown in FIG. 11.

Thus, according to the bit line sense amplifier 203 of the first embodiment, a pull-up voltage of the pull-up node N402 can be limited to (VDD−Vt), during the sensing operation. When the NMOS transistor 403a of the pull-up portion 403 has a threshold voltage substantially equal to that of the transfer transistor 303, the voltage level of the pull-up node N402 is substantially equal to the maximum voltage level of the bit signal BIT stored in the store node N302. That is, in the bit line sense amplifier according to the first embodiment, since the pull-up voltage of the pull-up node is limited to (VDD−Vt), the voltage of the bit signal is also limited to (VDD−Vt). Therefore, the semiconductor memory device having the bit line sense amplifier according to the first embodiment can prevent excessive current consumption and stress.

### SECOND EMBODIMENT

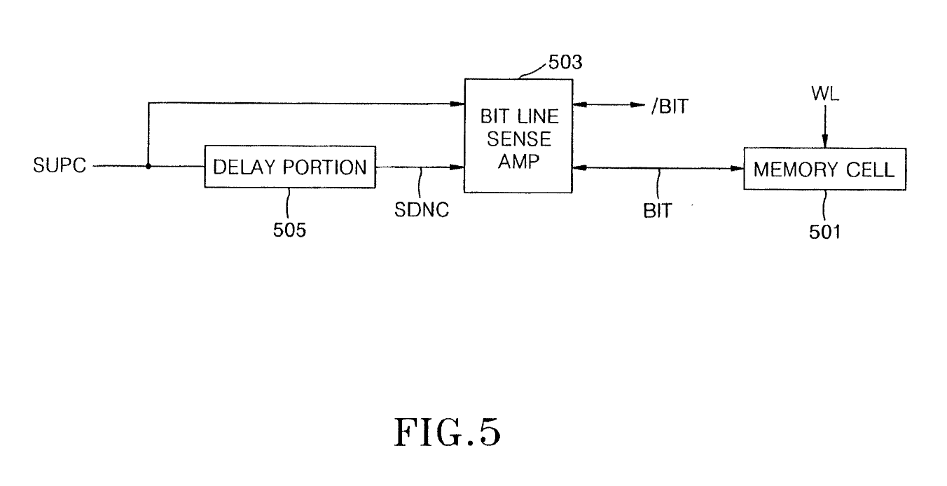

FIG. 5 is a schematic block diagram for explaining a bit line sensing operation in a semiconductor memory device having a bit line sense amplifier according to a second embodiment of the present invention. A bit line sense amplifier 503 senses a bit signal BIT and a complementary bit signal/BIT, and amplifies them. The operation of the bit line sense amplifier 503 is controlled by a pull-up control signal SUPC and a pull-down control signal SDNC. A delay portion 505 delays the pull-up control signal SUPC and outputs the delayed signal as the pull-down control signal SDNC. A memory cell 501 provides the bit signal BIT to the bit line sense amplifier 503 and stores the amplified bit signal BIT. Since the memory cell 501 in the second embodiment shown in FIG. 5 is substantially similar to the memory cell 201 in the first embodiment shown in FIG. 2, detailed description of the memory cell 501 is omitted in this specification.

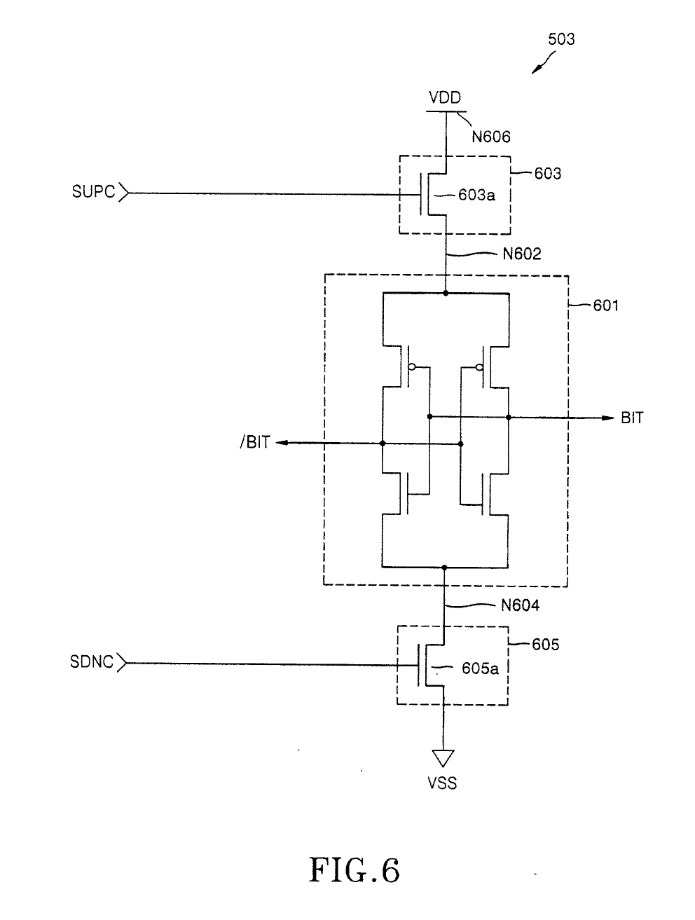

FIG. 6 is a circuit diagram for the bit line sense amplifier 503 shown in FIG. 5. Referring to FIG. 6, the bit line sense amplifier 503 includes an amplifying portion 601, a pull-up portion 603 and a pull-down portion 605. Since the amplifying portion 601 is substantially similar to the amplifying portion 401 in the first embodiment shown in FIG. 4, detailed description of the amplifying portion 601 is omitted.

The pull-up portion 603 is formed with an NMOS pull-up transistor 603a, of which a source is coupled to a pull-up node N602 and a drain is coupled to a power supply node N606. A voltage level supplied to the power supply node N606 is substantially equal to that of a word signal WL. Preferably, the voltage supplied to the power supply node N606 is an external power voltage VDD. Also, it is preferred that the threshold voltage of the pull-up transistor 603a is substantially equal to or less than that of the transfer transistor 303 in FIG. 3.

The pull-down portion 605 is formed with an NMOS pull-down transistor 605a, of which a drain is coupled to the pull-down node N604 and a source is coupled to a ground voltage VSS.

The pull-up transistor 603a is controlled by the pull-up control signal SUPC and the pull-down transistor 605a is controlled by the pull-down control signal SDNC. Voltage levels of both the pull-up control signal SUPC and the pull-down control signal SDNC go up to a level of the external power voltage VDD during a bit line sensing operation. Consequently, the voltage of the bit signal BIT amplified by the amplifying portion 601 is suppressed. That is, the pull-up voltage of the bit signal BIT is limited to (VDD−Vt), as shown in FIG. 11.

The voltage level of the pull-up node N602 is higher than the ground voltage VSS. The pull-up node N602 is the source of the pull-up transistor 603a, and the ground is the source of the pull-down transistor 605a. Therefore, the threshold voltage of the pull-up transistor 603a is higher than that of the pull-down transistor 605a, in the bit line sense amplifier in FIG. 6. In this case, the pull-down control signal SDNC is a delayed signal of the pull-up control signal SUPC, and therefore both the pull-up transistor 603a and the pull-down transistor 605a can be turned on almost simultaneously.

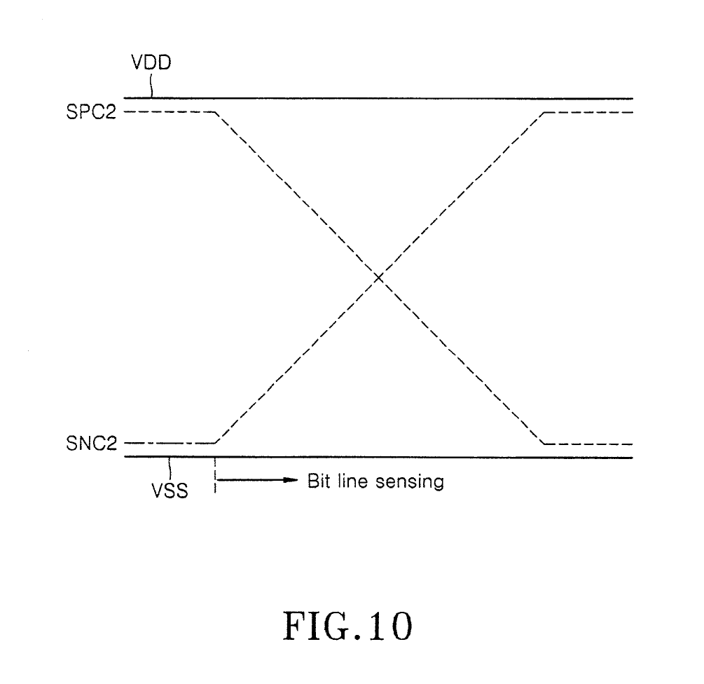

In this case, as shown in FIG. 10, a voltage symmetry of the bit signal BIT and the complementary bit signal/BIT in the second embodiment is remarkably improved, as compared with in the first embodiment.

### THIRD EMBODIMENT

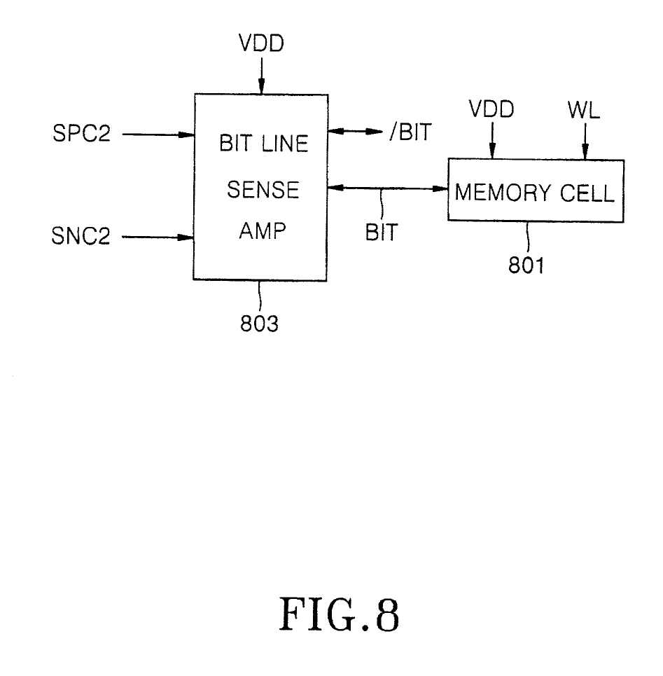

FIG. 8 is a schematic block diagram for explaining a bit line sensing operation in a semiconductor memory device having a bit line sense amplifier according to the third embodiment of the invention. A bit line sense amplifier 803 senses a bit signal BIT and a complementary bit signal/BIT, and amplifies them. The operation of the bit line sense amplifier 803 is controlled by a pull-up control signal SPC2 and a pull-down control signal SNC2. A memory cell 801 provides the bit signal BIT to the bit line sense amplifier 803 and stores the amplified bit signal BIT. Since the memory cell 801 in the third embodiment is substantially similar to the memory cell 201 according to the first embodiment shown in FIG. 2, detailed description of the memory cell 801 is omitted in this specification.

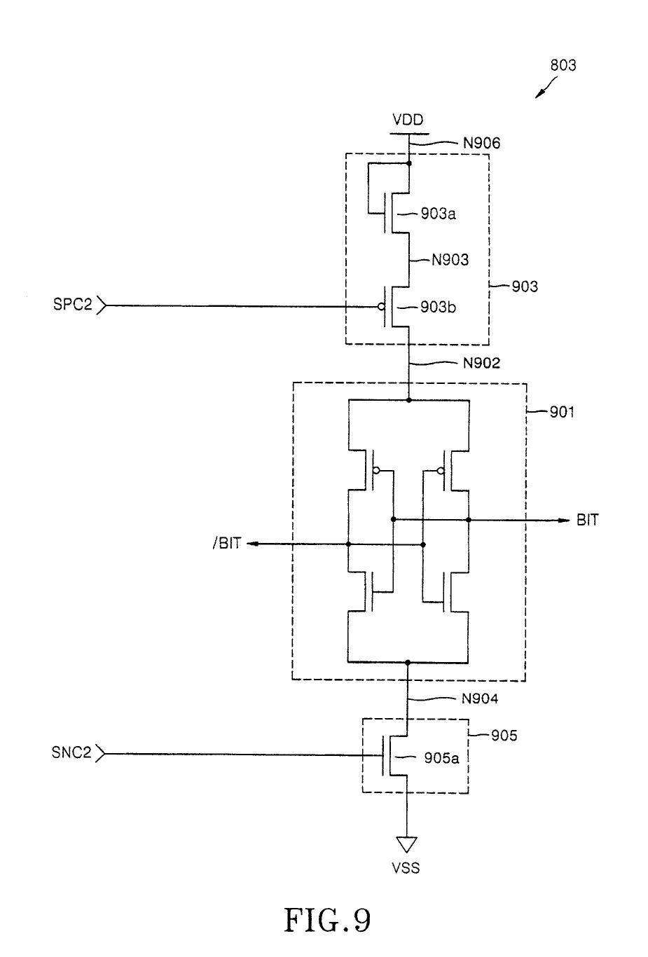

FIG. 9 is a circuit diagram for the bit line sense amplifier 803 shown in FIG. 8. Referring to FIG. 9, the bit line sense amplifier 803 includes an amplifying portion 901, a pull-up portion 903 and a pull-down portion 905. The amplifying portion 901 is also similar to the amplifying portion 401 according to the first embodiment, therefore detailed description of the amplifying portion 901 is omitted.

The pull-up portion 903 includes an NMOS transistor 903a and a PMOS transistor 903b. The NMOS transistor 903a drops a voltage level of a power supply node N906 by a threshold voltage, and then provides the dropped voltage to a source node N903. The PMOS transistor 903b is controlled by a pull-up control signal SPC2 and provides the voltage of the node N903, which is the dropped voltage of the power supply node N906 by the NMOS transistor 903a, to a pull-up node N902.

Preferably, the voltage of the power supply node N906 is substantially equal to that of the word signal WL. That is, it is preferred that the voltage supplied to the power supply node N906 is an external power voltage VDD. Also, the threshold voltage Vt of the NMOS transistor 903a is substantially equal to or less than that of the NMOS transfer transistor 303 shown in FIG. 3.

The pull-down portion 905 is formed with an NMOS transistor 905a, of which a drain is coupled to the pull-down node N904 and a source is coupled to a ground voltage VSS. The NMOS transistor 905a is controlled by a pull-down control signal SNC2. During a bit line sensing operation, both the pull-up control signal SPC2 and the pull-down control signal SNC2 are transited to the ground voltage VSS and the external power voltage VDD, respectively, as shown in FIG. 10.

In the bit line sense amplifier 903 according to the third embodiment of the invention, the voltage level of the source node N903 of the pull-up portion 903 is maintained as (VDD−Vt). Thus, during the bit line sensing operation, a pull-up voltage of the pull-up node N902 can be limited to (VDD−Vt). When the threshold voltage of the NMOS transistor 903a is substantially equal to that of the transfer transistor 303, the voltage level of the pull-up node N902 may be substantially equal to the maximum voltage level stored in the store node N302. That is, the maximum pull-up voltage of the bit signal BIT is substantially equal to the maximum voltage level stored in the store node N302. Thus, the semiconductor memory device having the bit line sense amplifier according to the third embodiment of the invention can lower current consumption and a stress.

As described above, according to the bit line sense amplifier of the invention, the pull-up voltage of the pull-up node is limited to (VDD−Vt) and the maximum pull-up voltage of the bit signal is limited to (VDD−Vt). Therefore, the semiconductor memory device having the bit line sense amplifier can minimize excessive current consumption and a stress.

While this invention has been particularly shown and described with reference to the first through the third embodiments thereof, it will be understood by those skilled in the art that various changes and equivalents may be made without departing from the spirit and scope of the invention. Therefore, it is intended that the invention not be limited to the particular embodiment disclosed as the best mode contemplated for carrying out this invention, but that the invention will include all embodiments within the scope of the appended claims.

What is claimed is:

1. A semiconductor memory device, comprising:
a bit line sense amplifier for sensing a bit signal and a complementary bit signal, and amplifying the bit signal and the complementary bit signal; and
a memory cell for storing the bit signal,
wherein the memory cell includes:
an NMOS transfer transistor, which is controlled by a word signal, for transferring the bit signal; and
a capacitor for storing the bit signal transferred by the NMOS transfer transistor,
wherein the bit line sense amplifier includes:
an amplifying portion for amplifying the bit signal and the complementary bit signal, the amplifying portion being disposed between a pull-up node and a pull-down node, and having two inverters cross-coupled as a latch;
a pull-up portion for pulling up a voltage level of the pull-up node, the pull-up portion being disposed between a power supply node and the pull-up node, having a first NMOS transistor, and being controlled by a control signal; and
a pull-down portion for pulling down a voltage level of the pull-down node, the pull-down portion being disposed between a ground voltage and the pull-down node, having a second NMOS transistor, and being controlled by the control signal,
wherein the word signal and the control signal are activated with a voltage level substantially equal to that of the power supply node.

2. The semiconductor memory device in accordance with claim 1, wherein the voltage of the power supply node is an external power voltage.

3. The semiconductor memory device in accordance with claim 1, wherein the first NMOS transistor includes a source coupled to the pull-up node, a drain coupled to the power supply node and a gate controlled by the control signal, and
wherein the second NMOS transistor includes a source coupled to the ground voltage, a drain coupled to the pull-down node and a gate controlled by the control signal.

4. The semiconductor memory device in accordance with claim 1, wherein a threshold voltage of the first NMOS transistor is substantially equal to or less than that of the NMOS transfer transistor.

5. The semiconductor memory device in accordance with claim 1, wherein the capacitor is formed with a third NMOS transistor.

6. A semiconductor memory device, comprising:
a bit line sense amplifier for sensing a bit signal and a complementary bit signal, and amplifying the bit signal and the complementary bit signal; and
a memory cell for storing the bit signal,
wherein the memory cell includes:
an NMOS transfer transistor, which is controlled by a word signal, for transferring the bit signal; and
a capacitor for storing the bit signal transferred by the NMOS transfer transistor,
wherein the bit line sense amplifier includes:
an amplifying portion for amplifying the bit signal and the complementary bit signal, the amplifying portion being disposed between a pull-up node and a pull-down node, and having two inverters cross-coupled as a latch;
a pull-up portion for pulling up a voltage level of the pull-up node, the pull-up portion being disposed between a power supply node and the pull-up node, having a first NMOS transistor, and being controlled by a pull-up control signal; and
a pull-down portion for pulling down a voltage level of the pull-down node, the pull-down portion being disposed between a ground voltage and the pull-down node, having a second NMOS transistor, and being controlled by a pull-down control signal,
wherein the pull-up control signal is activated before the pull-down control signal, in order that the first NMOS transistor is controlled together with the second NMOS transistor simultaneously.

7. The semiconductor memory device in accordance with claim 6, wherein the pull-up control signal, the pull-down control signal and the word signal are activated to a voltage level substantially equal to the voltage level of the power supply node.

8. The semiconductor memory device in accordance with claim 7, wherein the voltage of the power supply node is an external power voltage.

9. The semiconductor memory device in accordance with claim 6, wherein the first NMOS transistor has a source coupled to the pull-up node, a drain coupled to the power supply node and a gate controlled by the pull-up control signal, and
wherein the second NMOS transistor has a source coupled to the ground voltage, a drain coupled to the pull-down node and a gate controlled by the pull-down control signal.

10. The semiconductor memory device in accordance with claim 6, wherein a threshold voltage of the first NMOS transistor is substantially equal to or less than that of the NMOS transfer transistor.

11. The semiconductor memory device in accordance with claim 6, wherein the capacitor is formed with a third NMOS transistor.

12. A bit line sense amplifier for a semiconductor memory device, comprising:
an amplifying portion for amplifying a bit signal and a complementary bit signal, the amplifying portion being disposed between a pull-up node and a pull-down node, and having two inverters cross-coupled as a latch;
a pull-up portion for pulling up a voltage level of the pull-up node, the pull-up portion being disposed between a power supply node and the pull-up node, having a first NMOS transistor, and being controlled by a pull-up control signal; and
a pull-down portion for pulling down a voltage level of the pull-down node, the pull-down portion being disposed between a ground voltage and the pull-down node, having a second NMOS transistor, and being controlled by a pull-down control signal,
wherein the pull-up control signal is activated before the pull-down control signal, in order that the first NMOS transistor is controlled together with the second NMOS transistor simultaneously.

13. A bit line sense amplifier for a semiconductor memory device, comprising:
an amplifying portion for amplifying a bit signal and a complementary bit signal, the amplifying portion being disposed between a pull-up node and a pull-down node, and having two inverters cross-coupled as a latch;
a pull-up portion for pulling up a voltage level of the pull-up node in response to a pull-up control signal, the pull-up portion being disposed between a power supply node and the pull-up node; and
a pull-down portion for pulling down a voltage level of the pull-down node, the pull-down portion being disposed between a ground voltage and the pull-down node, and being controlled by a pull-down control signal,
wherein the pull-up portion includes a first transistor for dropping a voltage level of the power supply node by a predetermined voltage level; and a second transistor for providing a voltage of the power supply node dropped by the first transistor to the pull-up node.

14. The bit line sense amplifier in accordance with claim 13, wherein the first transistor is formed with an NMOS transistor.

15. A semiconductor memory device, comprising:
a bit line sense amplifier for sensing and amplifying a bit signal and a complementary bit signal; and
a memory cell for storing the bit signal,
wherein the memory cell includes:
an NMOS transfer transistor, which is controlled by a word signal, transferring the bit signal; and
a capacitor for storing the bit signal transferred by the NMOS transfer transistor,
wherein the bit line sense amplifier includes:
an amplifying portion for amplifying the bit signal and the complementary bit signal, the amplifying portion being disposed between a pull-up node and a pull-down node, and having two inverters cross-coupled as a latch;
a pull-up portion for pulling up a voltage level of the pull-up node, the pull-up portion being disposed between a power supply node and the pull-up node, and being controlled by a control signal and; and
a pull-down portion for pulling down a voltage level of the pull-down node, the pull-down portion being disposed between a ground voltage and the pull-down node, and being controlled by the control and,
wherein the pull-up portion further includes:
a first transistor for dropping a voltage level of the power supply node by a predetermined voltage level; and
a second transistor for providing a voltage of the power supply node dropped by the first transistor to the pull-up node, gated by a pull-up control signal.

16. The semiconductor memory device in accordance with claim 15, wherein the first transistor is formed with an NMOS transistor.

17. The semiconductor memory device in accordance with claim 15, wherein the voltage of the power supply node is an external power voltage.

18. The semiconductor memory device in accordance with claim 15, wherein a threshold voltage of the first transistor is substantially equal to or less than that of the NMOS transfer transistor.

19. The semiconductor memory device in accordance with claim 15, wherein the capacitor is formed with a third NMOS transistor.
